(19) United States
(12) Patent Application Publication
(10) Pub. No.: US 2012/0176751 A1
(43) Pub. Date: Jul. 12, 2012

(54) ELECTRONIC COMPONENT MODULE AND MANUFACTURING METHOD THEREFOR

(75) Inventors: Norio SAKAI, Nagaokakyo-shi (JP); Mayuko NISHIHARA, Nagaokakyo-shi (JP)

(73) Assignee: MURATA MANUFACTURING CO., LTD., Nagaokakyo-shi (JP)

(21) Appl. No.: 13/415,886

(22) Filed: Mar. 9, 2012

Related U.S. Application Data
(63) Continuation of application No. PCT/JP2010/005500, filed on Sep. 8, 2010.

(30) Foreign Application Priority Data
Sep. 11, 2009 (JP) 2009-209989

(51) Int. Cl. H05K 7/06; H05K 3/46; H05K 3/30

(52) U.S. Cl. 361/746; 29/841

(57) ABSTRACT

An electronic component module includes a substrate including a first electrode pattern and a first resist pattern on a first main surface thereof, a first electronic component mounted on the first main surface via the first electrode pattern, and a component-embedding resin layer provided on the first main surface so as to embed the first electronic component therein, and including, in an inside portion or a lateral portion thereof, an interlayer connection conductor connecting the first electrode pattern and an external connection electrode pattern disposed on a surface of the component-embedding resin layer to each other. The first electrode pattern and the first resist pattern are arranged so that the first resist pattern is disposed on top of a circumferential portion of the first electrode pattern.

### BACKGROUND OF THE INVENTION

1. Field of the Invention

The present invention relates to an electronic component module and a manufacturing method therefor, and more particularly, to the layout of an electrode pattern and a resist pattern in a substrate on which an electronic component is mounted.

2. Description of the Related Art

In the past, when an electronic component, such as a capacitor, a resistor, a semiconductor, or other electronic component is flip-chip (FC) mounted on a printed-wiring board (PWB) that defines a core substrate, an electrode pattern (wiring pattern) and a resist pattern (solder resist pattern) covering a portion other than the electrode pattern are formed with a distance (gap) provided therebetween on a main surface on the front side or back side of the printed-wiring board, and the electronic component is mounted on one electrode pad or a plurality of electrode pads (lands) in the electrode pattern through a connection conductor (solder bump or other suitable connection conductor) (see, for example, refer to Japanese Unexamined Patent Application Publication No. 2006-276001 (Abstract, paragraphs [0036], [0037], and [0045] to [0047], and FIGS. 1 and 2).

FIG. 4A is a cross-sectional view of the printed-wiring board 110, and FIG. 4B is a cross-sectional view of a circuit element 120 as an electronic component mounted on the printed-wiring board 110.

In addition, as illustrated in FIG. 4A, the printed board 110 includes a printed board-side solder bump 104b, a printed board-side land 106, a base material 105, a printed board-side resist 107, and other elements, and, in the insulating base material 105 including a ceramic or a thermoplastic resin, on a main surface (mounting surface) to which the circuit element 120 in FIG. 4B is mounted, a plurality of the substrate-side lands 106 and a plurality of the substrate-side resists 107 are formed with distances being set therebetween.

In addition, as illustrated in FIG. 4B, the circuit element 120 includes an interposer 101 that defines the main body of the element, and includes an element-side land 102 and an element-side resist 103, which are formed on one surface of the interposer 101 with a space therebetween, a solder bump 104a, and other elements.

FIG. 5 is a cross-sectional view in a state in which the circuit element 120 is mounted on the printed board 110. In addition, the element-side solder bump 104a in FIG. 4A and the substrate-side solder bump 104b in FIG. 4B are melted and jointed together, and thus, a solder bump 104 in FIG. 5 is formed and the circuit element 120 is mounted on the printed board 110.

Incidentally, substrates, such as the above-mentioned printed-wiring board and other substrates, include a substrate in which such an electronic component as the circuit element 120 is embedded in a component-embedding resin layer which defines a resin seal, thereby forming an electronic component module. This electronic component module is mounted on a mother substrate through an external connection electrode pattern while the external connection electrode pattern is stuck to the surface of the component-embedding resin layer. Furthermore, as this kind of electronic component module, there is also an electronic component module where, in order to enhance a component mounting density, electrode patterns are also formed on a main surface, in which the component-embedding resin layer of the substrate is formed, and a main surface on an opposite side so as to mount another electronic component such that the substrate has a double-sided mounting structure.

In addition, typically, in these electronic component modules, when the electronic component within the component-embedding resin layer and the other electronic components are mounted on the substrate, an electrode pattern and a resist pattern are arranged with a distance being set therebetween in the mounting surface of the substrate. For example, this is because the solder of a flip chip is also jointed on the side surface of the pad (land) of a wiring pattern, thereby improving reliability.

In the case of the above-mentioned module of the related art, when a resin defining the above-mentioned component-embedding resin layer is packed, since a distance is provided between the pad (land) of an electrode pattern and a resist pattern on the lower side of an electronic component, it is difficult for a resin to enter this portion and an insufficient amount of resin may be provided.

In addition, in the component-embedding resin layer, a bottomed via hole is formed by laser processing or drilling, the via hole is subjected to via fill plating or filled with conductive paste to form an interlayer connection conductor (via conductor or the like), and due to this interlayer connection conductor, electrode patterns located above and below the component-embedding resin layer are connected to each other. However, if a laser irradiation position deviates from the electrode patterns, a bare portion in the above-mentioned gap, on which no resist pattern in the substrate is formed, is irradiated with the laser, it is easy for a hole to be created in the substrate, and the substrate may be damaged.

In addition, while an electronic component module is being manufactured, since the electronic component module undergoes many wet processes including the above-mentioned via fill plating and the etching of the electrode pattern, a residue of the liquid solution used in the wet processes may occur. In addition, a large amount of the residue is likely to remain in a gap between the electrode pattern and the resist pattern. If the component-embedding resin layer is formed and resin-sealed in this state, in a reflow process performed when the electronic component module is mounted on a motherboard, solder extends from an interface between the component-embedding resin layer and the substrate or an interface between the component-embedding resin layer and an embedded electronic component, due to the influence of the residue, and there is a possibility that solder splash may occur.

In addition, the adhesion property of the peripheral side surface of the electrode pattern with respect to solder or a resin is relatively weak, and there is also a possibility that solder used to mount the electronic component travels along the peripheral side surface and extends therefrom and solder splash may occur.

### SUMMARY OF THE INVENTION

To overcome the problems described above, preferred embodiments of the present invention provide an electronic component module in which a component-embedding resin layer is provided on at least one main surface of a substrate, does not experience the problems of an insufficient amount of resin and damage to the substrate caused by laser processing or drilling in an interlayer connection conductor formation process, and has excellent properties, and also provide a manufacturing method therefor.

An electronic component module according to a preferred embodiment of the present invention preferably includes a substrate including a first electrode pattern and a first resist pattern on a first main surface thereof, a first electronic component mounted on the one main surface via the first electrode pattern, and a component-embedding resin layer arranged on the first main surface so as to embed the first electronic component therein, and including, in an inside portion or a lateral portion, an interlayer connection conductor connecting the first electrode pattern and an external connection electrode pattern provided on a surface of the component-embedding resin layer to each other. The first electrode pattern and the first resist pattern are preferably arranged so that the first resist pattern is located on top of a circumferential portion of the first electrode pattern.

In addition, the substrate preferably further includes a second electrode pattern and a second resist pattern on a second main surface thereof. A second electronic component is mounted on the second main surface through the second electrode pattern, and the second electrode pattern and the second resist pattern are arranged with a space therebetween so as not to overlap with each other.

Furthermore, in the electronic component module, the other main surface of the substrate is preferably not resin-sealed.

A manufacturing method for an electronic component module according to yet another preferred embodiment of the present invention preferably includes a step of disposing a first electrode pattern and a first resist pattern on a first main surface of a substrate, a step of mounting a first electronic component to the first main surface through the first electrode pattern, and a step of providing, on the first main surface, a component-embedding resin layer so as to embed the first electronic component therein and includes, in an inside portion or a lateral portion, an interlayer connection conductor connecting the first electrode pattern and an external connection electrode pattern on a surface of the component-embedding resin layer to each other, wherein the first electrode pattern and the first resist pattern are arranged so that the first resist pattern is located on top of a circumferential portion of the first electrode pattern.

In addition, the manufacturing method for an electronic component module preferably further includes a step of disposing a second electrode pattern and a second resist pattern on a second main surface of the substrate, and a step of mounting a second electronic component to the second main surface through the second electrode pattern, wherein the second electrode pattern and the second resist pattern are arranged with a space therebetween so as not to overlap with each other.

In an electronic component module according to a preferred embodiment of the present invention, a first electrode pattern and a first resist pattern on a first main surface of a substrate are arranged so that the first resist pattern is located on top of the circumferential portion of the first electrode pattern. The electronic component module has a structure in which, in this state, a component-embedding resin layer in which a first electronic component is embedded is provided on the one main surface, and in the inside portion or lateral portion thereof, an interlayer connection conductor connects the first electrode pattern and an external connection electrode pattern on a surface of the component-embedding resin layer to each other.

In this case, there is no gap as in the related art between a pad (land) of the electrode pattern and the resist pattern on the one main surface. Therefore, the gap does not exist on the lower side of the first electronic component, the lower side of the electronic component substantially comes into contact with the first resist pattern, and a shortage of resin is not likely to occur.

In addition, when a via hole for the interlayer connection conductor is formed in the component-embedding resin layer by laser processing or drilling, even if a laser irradiation position deviates from the electrode pattern, since resist patterns are provided in these portions, a hole is not created in the substrate, and the substrate is not damaged.

Furthermore, a gap between the first electrode pattern and the first resist pattern on the one main surface on which the component-embedding resin layer is provided is relatively small, and a residue that occurs due to a wet manufacturing process is less likely to accumulate. Therefore, in a reflow process or other mounting process performed when the electronic component module is mounted on a motherboard, a conductive bonding material, such as solder or other suitable material, does not extend due to the influence of the above-mentioned residue, and there is little possibility that solder flash will occur. Furthermore, since the peripheral side surface of the first electrode pattern is covered by the first resist pattern, solder splash traveling along the peripheral side surface does not occur.

Accordingly, an electronic component module is provided that has a structure in which a component-embedding resin layer is provided on at least one main surface of a substrate, a shortage of resin does not occur, damage to a substrate due to laser processing or drilling in an interlayer connection conductor formation process does not occur, and the electronic component module has good reliability.

In addition, since a second electrode pattern and a second resist pattern are preferably disposed on another main surface of the substrate with a distance being provided therebetween so as not to overlap with each other, and in this state, a second electronic component is mounted on the other main surface via the second electrode pattern, it is possible to configure the substrate so as to have a double-sided mounting structure by arranging the layouts of the electrode patterns and the resist patterns so as to differ depending on the main surfaces.

Furthermore, since the other main surface of the substrate preferably is not resin-sealed, there is no shortage of resin and no damage of the substrate due to laser processing or drilling for a via hole. In addition, the second electrode pattern and the second resist pattern are arranged with a space therebetween so as not to overlap with each other, and thus, residue occurring in the wet manufacturing process does not accumulate.

In addition, preferably, the layouts of the electrode patterns and the resist patterns are arranged to differ depending on the one main surface side providing therein the component-embedding resin layer and the other main surface side that is not resin-sealed, depending upon the individual properties thereof, the first resist pattern is disposed on the one main surface so as to be located on top of the circumferential portion of the first electrode pattern, and the second electrode pattern and the second resist pattern are arranged on the other main surface with a space therebetween so as not to overlap with each other. Accordingly, it is possible to greatly improve the characteristics of the substrate having the double-sided mounting structure in which the component-embedding resin layer is provided on the one main surface of the substrate and the other main surface side is not resin-sealed.

In a manufacturing method for an electronic component module according to a preferred embodiment of the present invention, an electronic component module is preferably manufactured in which the first resist pattern is disposed on the one main surface of the substrate so as to be located on top of the circumferential portion of the first electrode pattern, the first electronic component is embedded in the component-embedding resin layer on the first main surface via a first electrode pattern, and the interlayer connection conductor is arranged to connect the first electrode pattern and the external connection electrode pattern on a surface to each other.

In addition, in a manufacturing method for an electronic component module according to a preferred embodiment of the present invention, it is possible to manufacture an electronic component module in which the second electrode pattern and the second resist pattern are formed on the second main surface of the substrate with a distance being provided therebetween so as not to overlap with each other and the second electronic component is mounted on the second main surface through the second electrode pattern.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of an electronic component module according to a preferred embodiment of the present invention.

FIGS. 2A and 2B are plan views of one portion and another portion in the electronic component module in FIG. 1.

FIGS. 3A to 3H are cross-sectional views showing a manufacturing process of the electronic component module in FIG. 1.

FIGS. 4A and 4B are a cross-sectional view of a substrate of a module of the related art and a cross-sectional view of a circuit element as an electronic component to be mounted.

FIG. 5 is a cross-sectional view of a module of the related art in which the circuit element in FIG. 4B is mounted on the substrate in FIG. 4A.

### DETAILED DESCRIPTION OF THE PREFERRED EMBODIMENTS

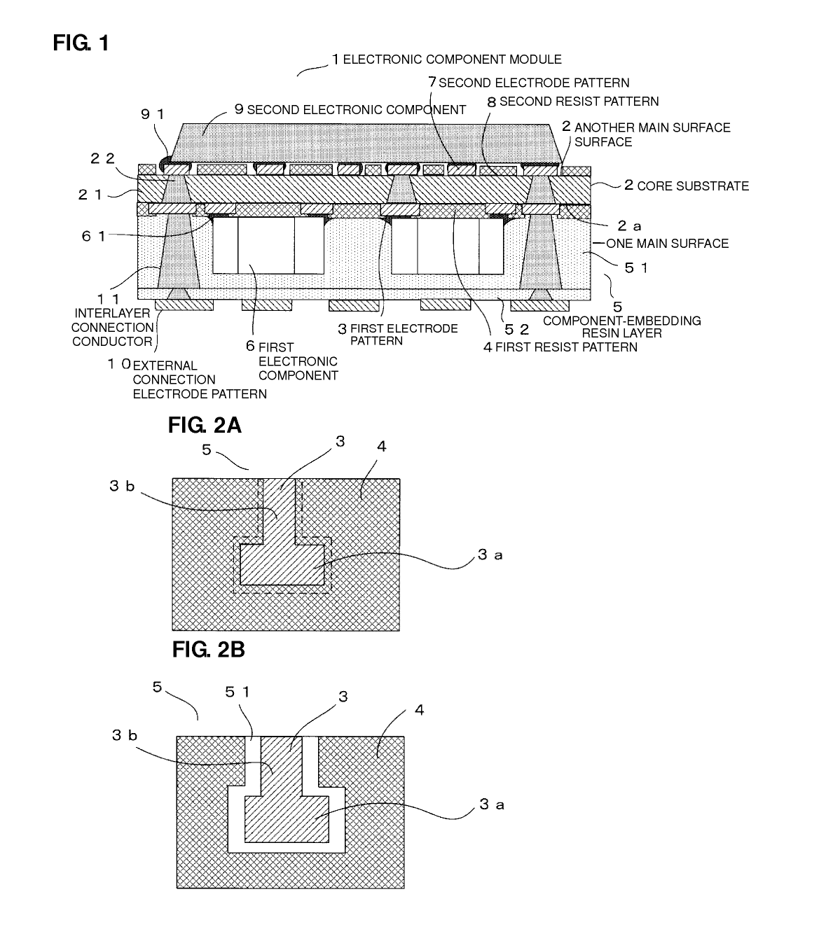

Preferred embodiments of the present invention will be described with reference to FIG. 1 to FIG. 3.

The configuration of an electronic component module 1 according to a present preferred embodiment of the present invention will be described with reference to FIGS. 1 and 2.

FIG. 1 is the cross-sectional view of the electronic component module 1 according to the present preferred embodiment, and the electronic component module 1 preferably includes a core substrate 2 having a double-sided mounting structure. In the core substrate 2, preferably, a first electrode pattern 3 and a first resist pattern 4 are included on one main surface (bottom surface) 2a, and one first electronic component 6 or a plurality of the first electronic components 6 that are embedded in a component-embedding resin layer 5 are mounted via the first electrode pattern 3. In addition, preferably, a second electrode pattern 7 and a second resist pattern 8 are included on another main surface (top surface) 2b of the core substrate 2, and one second electronic component 9 or a plurality of the second electronic components 9 are mounted through the second electrode pattern 7.

The core substrate 2 preferably includes various kinds of resin substrates, such as an LTCC (Low Temperature Co-fired Ceramics) substrate, or other suitable substrate, for example, and one via conductor 22 or a plurality of the via conductors 22 are provided in a base material layer 21 so as to connect individual electrode pads (lands) of the electrode patterns 3 and 7 on both of the main surfaces 2a and 2b as appropriate. The via conductor 22 is preferably formed by performing well-known via fill plating or filling processing of conductive paste on a through hole, for example.

The electrode patterns 3 and 7 are preferably copper foil patterns, for example, and are formed using well-known etching or other suitable method. The resist patterns 4 and 8 are preferably formed by printing or coating well-known solder resist on a portion other than the electrode patterns 3 and 7 in the main surfaces 2a and 2b, for example. In addition, the thicknesses of the electrode patterns 3 and 7 are preferably about 10 μm to about 20 μm, for example, and the thicknesses of the resist patterns 4 and 8 are preferably about 30 μm to about 40 μm, for example.

For example, the component-embedding resin layer 5 preferably includes a resin layer 51 in which thermosetting resin and filler are mixed and a thin adhesive layer 52 on a side (front surface side) of the resin layer 51 opposite to the core substrate 2. In addition, in the component-embedding resin layer 5, the first electronic component 6 is embedded, and in an inside portion or a lateral portion of the component-embedding resin layer 5, one interlayer connection conductor (via conductor) 11 or a plurality of the interlayer connection conductors 11 are arranged to connect the first electrode pattern 3 and an external connection electrode pattern 10 described later to each other as appropriate. In addition, examples of the thermosetting resin include epoxy resin, phenol resin, cyanate resin, and other suitable resins, and examples of the filler include inorganic powder such as silica powder, alumina powder, and other suitable fillers.

The adhesive layer 52 is preferably provided so as to adhere the external connection electrode pattern 10 to the front surface side of the component-embedding resin layer 5, and includes the same or substantially the same thermosetting resin as the resin layer 51 or thermosetting resin different from the resin layer 51. In the same or substantially the same manner as the via conductor 22, each interlayer connection conductor 11 is preferably formed by performing via fill plating or filling processing of conductive paste on a via hole, for example. Each interlayer connection conductor 11 is preferably constricted in the portion of the adhesive layer 52.

For example, the first electronic component 6 is preferably a chip component, such as a capacitor, a coil, a transistor, or other suitable chip component, and the second electronic component 9 is preferably an integrated circuit element or other suitable component, which is larger in size than the first electronic component 6, and flip-chip (FC) mounted on the electrode patterns 3 and 7 preferably using reflow soldering of a solder bump or other suitable method, for example. In addition, reference characters “61” and “91” in FIG. 1 indicate solder.

The external connection electrode pattern 10 is a terminal preferably used to connect and mount the electronic component module 1 to a mother substrate or other suitable substrate.

In addition, the first electrode pattern 3 and the first resist pattern 4 on a main surface 2a side, covered by the resin of the component-embedding resin layer 5, are preferably arranged so that the first resist pattern 4 is located on top of the circumferential portion of the first electrode pattern 3.

FIG. 2A illustrates an example of the overlapping of the first electrode pattern 3 and the first resist pattern 4. In this manner, the circumferential portion of the first electrode pattern 3 including a pad portion 3a in which conductive bonding material, such as solder or other suitable material, is provided, and a wiring portion 3b defining a lead is preferably covered by the first resist pattern 4. Therefore, there is no gap between the first electrode pattern 3 and the first resist pattern 4, and the base material layer 21 is not exposed.

In this case, a gap does not exist on the lower side of the first electronic component 6 attached to the electrode pad (land) of the first electrode pattern 3, the lower side of the first electronic component 6 is in contact with the first resist pattern 4, and resin is not necessary. Accordingly, the shortage of resin is less likely to occur.

In addition, when, in the component-embedding resin layer 5, a via hole for the interlayer connection conductor 11 is formed by laser processing or drilling so as to extend from the front surface side of the component-embedding resin layer 5 to the first electrode pattern 3, even if a laser irradiation position deviates to the circumferential portion of the first electrode pattern 3, since the first resist pattern 4 is provided in those portions, a laser beam is blocked by the first resist pattern 4. Therefore, no hole is created or no flaw occurs in the base material layer 21 of the core substrate 2, and the core substrate 2 is not damaged.

Furthermore, there is preferably no gap between the first electrode pattern 3 and the first resist pattern 4 in the main surface 2a on which the component-embedding resin layer 5 is provided. In addition, the lower side of the first electronic component 6 is arranged so as to come into contact with the first resist pattern 4, and it is not necessary to provide resin. Accordingly, the shortage of resin is not likely to occur. In addition, a residue occurring in a wet manufacturing process, such as the formation of the first electrode pattern 3 and the first resist pattern 4 or the formation of the via hole for the interlayer connection conductor 11, is not likely to be confined in the component-embedding resin layer 5. Therefore, in a reflow process or other suitable process performed when the manufactured electronic component module 1 is mounted on a motherboard (the illustration thereof is omitted), solder does not extend from an interface between the component-embedding resin layer 5 and the core substrate 2 or an interface between the component-embedding resin layer 5 and the electronic component 6 due to the influence of the residue, and a product defect, such as solder splash, does not occur. Furthermore, since the peripheral side surface of the first electrode pattern 3 is covered by the first resist pattern 4, the solder 61 used when the electronic component 6 is mounted on the core substrate does not flow along the peripheral side surface and solder splash.

Accordingly, an electronic component module 1 is provided that preferably includes the resin-sealed component-embedding resin layer 5 on the one main surface 2a of the core substrate 2 and does not have a shortage of resin. In addition, the damage of the core substrate 2 due to laser processing or drilling in the formation process of the interlayer connection conductor 11 is prevented and the electronic component module 1 has excellent reliability.

Next, the second electrode pattern 7 and the second resist pattern 8 are preferably disposed on the other main surface 2b of the core substrate 2 with a gap provided therebetween so as not to overlap with each other, and in this state, the second electronic component 9 is mounted on the other main surface 2b via the second electrode pattern 7.

FIG. 2B illustrates a preferable example of the layouts of the second electrode pattern 7 and the second resist pattern 8. The second electrode pattern 7 and the second resist pattern 8 are arranged with a gap provided therebetween so as not to overlap with each other. Accordingly, the core substrate 2 has a double-side mounting structure in which the layouts of the electrode patterns 3 and 7 and the resist patterns 4 and 8 differ depending on the main surfaces 2a and 2b. In addition, the residue remaining in the core substrate 2 in the above-mentioned wet manufacturing process is effectively removed from the gap portion.

Furthermore, since the other main surface 2b of the core substrate 2 is not resin-sealed, there is no shortage of resin and no damage of the substrate due to laser processing or drilling for a via hole in the other main surface 2b. In addition, the second electrode pattern 7 and the second resist pattern 8 are arranged with a space therebetween so as not to overlap with each other, and thus, a residue, such as a smear, for example, occurring in the wet manufacturing process is effectively removed in a final form as an electronic component module.

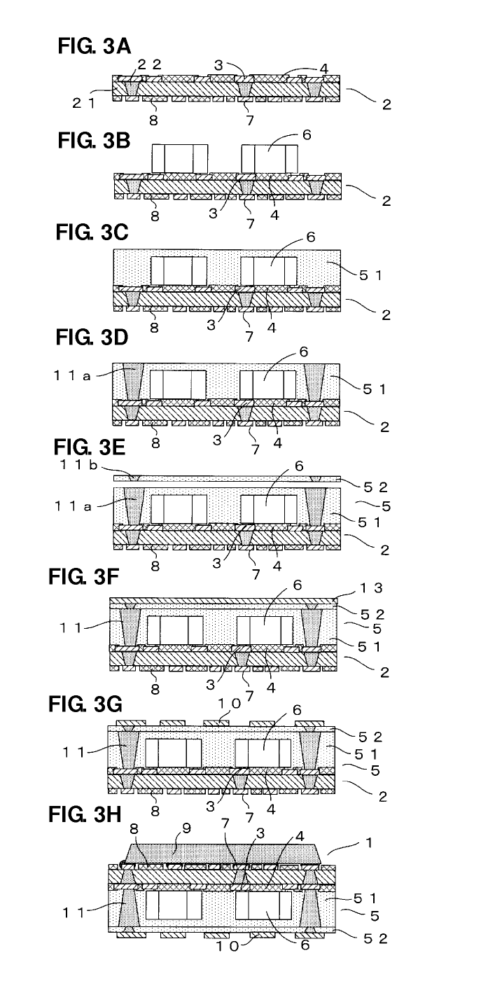

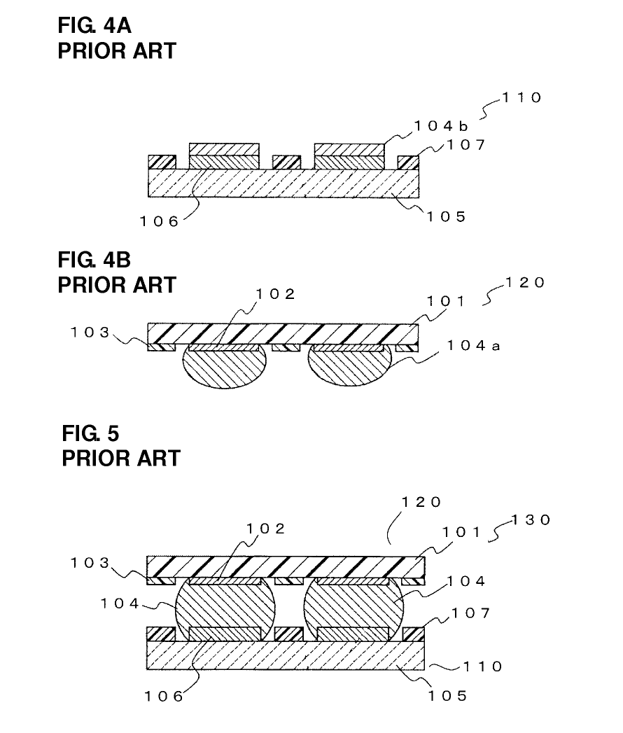

A manufacturing method for the electronic component module 1 according to a preferred embodiment of the present invention will be described with reference to FIGS. 3A-3H.

In a process shown in FIG. 3A, the core substrate 2 is prepared and arranged so as to be turned upside down. In this preferred embodiment, in the core substrate 2 preferably including a printed board, an LTCC substrate, or other suitable substrate, the electrode patterns 3 and 7 are formed in the main surfaces 2a and 2b of the base material layer 21 preferably by etching, printing, or other suitable method. Furthermore, in the one main surface 2a, the first resist pattern 4 is formed so as to overlap with the circumferential portion of the first electrode pattern 3 preferably by printing or coating solder resist, for example. In the other main surface 2b, the second electrode pattern 7 and the second resist pattern 8 are formed with a space therebetween so as not to overlap with each other preferably by printing or coating solder resist, for example. In addition, in the base material layer 21, the via conductor 22 is formed preferably by laser processing or drilling, for example.

In a process shown in FIG. 3B, the first electronic component 6 is mounted on the main surface 2a of the core substrate 2 via the first electrode pattern 3. This mounting is performed by mounting the electrode of the first electronic component 6 on the pad of the first electrode pattern 3 via a solder bump and solder-jointing the first electronic component 6 to the first electrode pattern 3 by a reflow heating process.

In a process shown in FIG. 3C, for example, a sheet-form or liquid uncured (B stage) thermosetting resin is preferably packed so that the first electronic component 6 is embedded on the main surface 2a of the core substrate 2, and the resin layer 51 is formed by thermal curing, for example.

In a process shown in FIG. 3D, due to laser processing or drilling, via holes are formed in the cured resin layer 51 so that the electrode pattern 3 is exposed, and thereafter, after being subjected to a desmear process and a drying process, these via holes are preferably subjected to via fill plating or the filling processing of conductive paste, thereby forming the via conductor 11a. After that, the via conductor 11a is cured.

In a process shown in FIG. 3E, in order to bond the external connection electrode pattern 10 to the surface (top surface) of the component-embedding resin layer 5 formed by the cured resin layer 51, the uncured thin-layered adhesive layer 52 including the same or substantially the same resin as the resin layer 51 or a resin different from the resin layer 51 is prepared, and the adhesive layer 52 is bonded to the resin layer 51 preferably by vacuum pressing or other suitable method, for example. In addition, in the adhesive layer 52, a via conductor 11b is preferably formed at the position corresponding to the via conductor 11a in the resin layer 51.

In a process shown in FIG. 3F, for example, copper foil 13 is preferably attached to the top surface of the uncured adhesive layer 52 bonded to the resin layer 51, and by heating and drying, the adhesive layer 52 and the via conductor 11b are cured, thereby forming, on the core substrate 2, the resin-sealed component-embedding resin layer 5 to which the copper foil 13 is attached. In this preferred embodiment, due to the via conductors 11a and 11b, the interlayer connection conductor having a constriction is formed within the component-embedding resin layer 5.

In a process shown in FIG. 3G, the copper foil 13 is patterned preferably by etching processing or other suitable method, the external connection electrode pattern 10 is formed on the surface of the component-embedding resin layer 5, and due to the interlayer connection conductor 11, the first electrode pattern 3 and the external connection electrode pattern 10 on the surface of the component-embedding resin layer 5 are connected to each other. In addition, as necessary, plating processing is preferably performed on the electrode patterns 3 and 10, thereby forming a plated film.

In a process shown in FIG. 3H, the core substrate 2 and the component-embedding resin layer 5 adhered thereto is preferably turned upside down, the layouts of the second electrode pattern 7 and the second resist pattern 8 are set in an uppermost layer, the external connection electrode pattern 10 is set in a lowermost layer, and the second electronic component is attached and mounted on the second electrode pattern 7 preferably by solder reflow, for example, thereby manufacturing the electronic component module 1.

Accordingly, in the electronic component module 1, the layouts of the electrode patterns 3 and 7 and the resist patterns 4 and 8 differ depending on the one main surface side 2a in the core substrate 2 providing therein the resin-sealed component-embedding resin layer 5 and the other main surface side 2b providing therein no component-embedding resin layer 5, in response to the individual properties thereof, the first resist pattern 4 is preferably arranged on the one main surface 2a so as to be located on top of the circumferential portion of the first electrode pattern 3, and the second electrode pattern 7 and the second resist pattern 8 are preferably disposed on the other main surface 2b with a space therebetween so as not to overlap with each other. Therefore, it is possible to provide the electronic component module 1 having the structure shown in FIG. 1, in which the electronic components 6 and 9 are double-side mounted on the core substrate 2 and in which the electronic component module 1 has excellent reliability, and the manufacturing method therefor.

In addition, the present invention is not limited to the above-mentioned preferred embodiments, and in addition to the above-mentioned preferred embodiments, it is possible to make various modifications without departing from the spirit of the present invention. For example, while, in the above-described preferred embodiments, the interlayer connection conductor 11 is preferably formed within the component-embedding resin layer 5, the interlayer connection conductor 11 may be formed in the lateral portion of the component-embedding resin layer 5, depending upon the layouts of the first electrode pattern 3 and the external connection electrode pattern 10.

In addition, while, in the above-described preferred embodiments, a configuration has been provided in which the other main surface 2b side of the core substrate 2 preferably is not resin-sealed, the other main surface 2b side of the core substrate 2 may also have a configuration of a double-side mounting substrate in which a resin seal is performed in the component-embedding resin layer in the same or substantially the same manner as the one main surface 2a. In addition, in some cases, while performing no processing on the other main surface 2b side of the core substrate 2, the core substrate 2 may be subjected to single-side mounting.

The substrate according to preferred embodiments of the present invention is not limited to the core substrate 2 including a single-layer substrate, and may also be a multilayer substrate in which a plurality of insulation layers are laminated, for example.

In addition, it should be understood that the shapes and the sizes of the electrode patterns 3, 7, and 10, the width of a peripheral portion of the first electrode pattern 3 in which the first electrode pattern 3 and the first register pattern 4 overlap with each other, a distance between the second electrode pattern 7 and the second register pattern 8, and other dimensions and parameters may be suitably set in accordance with the manufacturing conditions of the electronic component module.

Furthermore, the resin layer 51 in the component-embedding resin layer 5 may also be thermoplastic resin, light curing resin, or other suitable resin, and the electronic components 6 and 9 may be any suitable components.

Next, for example, using the same method as the manufacturing method of the above-described preferred embodiment, an aggregation of a plurality of electronic component modules may be formed, and by singulation thereof, a final electronic component module may also be manufactured.

Various preferred embodiments of the present invention may be applied to an electronic component module in which various components are embedded and a manufacturing method therefor.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component module comprising:
a substrate including a first electrode pattern and a first resist pattern on a first main surface thereof;
a first electronic component mounted on the first main surface via the first electrode pattern; and
a component-embedding resin layer provided on the first main surface so as to embed the first electronic component therein, and including, in an inside portion or a lateral portion thereof, an interlayer connection conductor connecting the first electrode pattern and an external connection electrode pattern disposed on a surface of the component-embedding resin layer to each other; wherein
the first electrode pattern and the first resist pattern are arranged so that the first resist pattern is located on top of a circumferential portion of the first electrode pattern.

2. The electronic component module according to claim 1, wherein
the substrate includes a second electrode pattern and a second resist pattern on a second main surface thereof opposite to the first main surface;
a second electronic component is mounted on the second main surface via the second electrode pattern; and
the second electrode pattern and the second resist pattern are disposed with a space therebetween so as not to overlap with each other.

3. The electronic component module according to claim 2, wherein
the second main surface of the substrate is not resin-sealed.

4. A manufacturing method for an electronic component module, comprising:
a step of disposing a first electrode pattern and a first resist pattern on a first main surface of a substrate;
a step of mounting a first electronic component on the first main surface via the first electrode pattern; and
a step of providing, on the first main surface, a component-embedding resin layer so as to embed the first electronic component therein, the component-embedding resin layer includes, in an inside portion or a lateral portion, an interlayer connection conductor connecting the first electrode pattern and an external connection electrode pattern on a surface of the component-embedding resin layer to each other; wherein
the first electrode pattern and the first resist pattern are arranged so that the first resist pattern is located on top of a circumferential portion of the first electrode pattern.

5. The manufacturing method for an electronic component module according to claim 4, the manufacturing method further comprising:
a step of disposing a second electrode pattern and a second resist pattern on a second main surface of the core substrate; and
a step of mounting a second electronic component on the second main surface via the second electrode pattern; wherein
the second electrode pattern and the second resist pattern are disposed with a space therebetween so as not to overlap with each other.
